(19) United States
(12) Patent Application Publication
(10) Pub. No.: US 2026/0356238 A1
(43) Pub. Date: Nov. 12, 2026

(54) Screening Method, Program Product, Management System, Charging Point System, and Charging Point

(71) Applicant: Mercedes-Benz Group AG, Stuttgart (DE)

(72) Inventors: Chen LIU, Beijing (CN); Xiaoxi XU, Beijing (CN)

(21) Appl. No.: 19/514,955

(22) PCT Filed: Aug. 15, 2024
(86) PCT No.: PCT/EP2024/025245

§ 371 Date: Feb. 27, 2026

(30) Foreign Application Priority Data
Aug. 29, 2023 (CN) 202311101612.5

(51) Int. Cl. B60L 53/68; B60L 53/67; G01R 31/40

(52) U.S. Cl. CPC B60L 53/68; B60L 53/67; G01R 31/40

(57) ABSTRACT

A method for screening for an abnormal charging point includes a screening process. The screening process includes an acquisition step in which information of a charging interface state of a charging point during at least one charging task of the charging point is acquired and a screening step in which for each charging task, screening is performed to determine whether a hopping sequence of the charging interface state of the charging point meets a specific hopping sequence, and when so, the charging point is identified to be normal, or when not, the charging point is identified as an abnormal charging point.

### BACKGROUND AND SUMMARY OF THE INVENTION

The present application relates to a method for screening for an abnormal charging point, a computer program product, a charging point management system, a charging point system, and a charging point.

Conventional fuel vehicles are increasingly being replaced by electric vehicles for environmental reasons. Electric vehicles need to be charged via charging points. There are currently many charging point operators that own respective charging points. However, this is often inconvenient for a user, because the user can only see, by means of an application program of a charging point operator, charging points of the charging point operator, but the number of charging points of a charging point operator is limited, and the nearest charging points may be far away from the current location of the user.

For this reason, a charging point aggregation platform has gradually become a growing trend. The charging point aggregation platform aggregates charging points of different charging point operators, so that users can select charging points from different charging point operators that are closest to their current locations by means of one platform.

In order to monitor charging points, the charging point operators communicate with charging points owned thereby via a network, especially a wireless network. The charging point aggregation platform generally communicates only with the charging point operators and obtains charging point information from the charging point operators. Communication protocols and software designs of different charging point operators generally differ from each other, so the charging point aggregation platform generally does not directly manage the charging points, but the respective charging points are generally managed by the charging point operators themselves. However, this is obviously inconvenient for the charging point aggregation platform.

An objective of the present application is to provide a method for screening for an abnormal charging point, so that a charging point aggregation platform can simply and reliably screen out abnormal charging points uniformly at a platform level on the basis of information obtained from charging point operators.

According to a first aspect of the present application, there is provided a method for screening for an abnormal charging point. The method comprises a screening process, and the screening process comprises the following steps:
an acquisition step, in which information of a charging interface state of a charging point during at least one charging task of the charging point is acquired; and
a screening step, in which for each charging task, screening is performed to determine whether a hopping sequence of the charging interface state of the charging point meets a specific hopping sequence, and if so, the charging point is identified to be normal, or if not, the charging point is identified as an abnormal charging point.

According to an optional embodiment of the present application, the charging interface state comprises at least three states, namely A, B, and C, wherein A represents that a charging interface of the charging point is idle, B represents that the charging interface of the charging point is occupied but charging is not performed, and C represents that the charging interface of the charging point is occupied and charging is performed.

According to an optional embodiment of the present application, there are four specific hopping sequences:
A-B-C-B-A;
A-B-C-A;
A-C-B-A; and
A-C-A.

In the screening step, if the hopping sequence of the charging interface state of the charging point does not meet any one of the four specific hopping sequences, then the charging point is identified as an abnormal charging point.

By means of this method, it is possible to simply and conveniently screen out an abnormal charging point. In particular, for a charging point aggregation platform, the charging points can conveniently be monitored uniformly at the platform level on the basis of the charging point information obtained from the charging point operators without additional modification, so as to screen out abnormal charging points. The “hopping sequence of the charging interface state” refers in particular to a change in the charging interface state of the charging point from the start to the end of a charging task, rather than a change in a period of time within a charging task.

According to an optional embodiment of the present application, in the acquisition step, a charging point aggregation platform acquires the information of the charging point via an operator system of a charging point operator responsible for the charging point; and in the screening step, the hopping sequence of the charging interface state of the charging point is screened by the charging point aggregation platform.

According to an optional embodiment of the present application, the screening process comprises an anomaly count monitoring step, in which if the charging point is identified as an abnormal charging point twice in succession in two screening processes performed for a current charging task and a previous charging task and/or if the number of times the charging point is identified as an abnormal charging point in a plurality of screening processes performed for a plurality of charging tasks up to the current charging task exceeds a predetermined count, then the charging point is identified to indeed be abnormal.

According to an optional embodiment of the present application, the method comprises a handling process that is performed for the abnormal charging point.

According to an optional embodiment of the present application, the handling process comprises a restart step in which the charging point is restarted.

According to an optional embodiment of the present application, the handling process comprises a handling step in which a signal indicating that the charging point is abnormal is outputted and/or the charging point is shut down and/or the charging point is made non-selectable by a user on an application program.

According to an optional embodiment of the present application, the handling step is performed for the charging point that is identified to indeed be abnormal by the anomaly count monitoring step.

According to an optional embodiment of the present application, the restart step is performed for the charging point that is not identified to indeed be abnormal in the anomaly count monitoring step.

According to an optional embodiment of the present application, the method comprises a self-checking monitoring process, in which self-checking conditions of the charging point are monitored at least before the charging task.

According to an optional embodiment of the present application, the self-checking monitoring process comprises a self-checking monitoring step, in which whether the charging point is self-checked to be in a fault state and/or off-network state is monitored, and if a result of the self-checking monitoring step is positive, the charging point is identified as an abnormal charging point.

According to an optional embodiment of the present application, in the self-checking monitoring step, the duration of the fault state and/or off-network state is additionally taken into account when the charging point is identified to be abnormal.

According to an optional embodiment of the present application, the self-checking monitoring process comprises a restart count monitoring step, if the result of the self-checking monitoring step is positive, then the restart count monitoring step is performed, and in the restart count monitoring step, if it is detected that the number of times the charging point is restarted exceeds a preset count, then the charging point is identified to indeed be abnormal.

According to an optional embodiment of the present application, the handling step is performed for the charging point that is identified to indeed be abnormal by the restart count monitoring step.

According to an optional embodiment of the present application, the restart step is performed for the charging point that is not identified to indeed be abnormal in the restart count monitoring step.

According to an optional embodiment of the present application, in the screening step, screening is performed to determine whether the duration for which the charging interface state is C exceeds a charging duration threshold and/or screening is performed to determine whether the duration taken to complete each charging task exceeds a task duration threshold.

According to a second aspect of the present application, there is provided a computer program product comprising computer program instructions, wherein, when the computer program instructions are executed by one or more processors, the processor is capable of performing the aforementioned method for screening for an abnormal charging point.

According to a third aspect of the present application, there is provided a charging point management system configured to perform the aforementioned method for screening for an abnormal charging point to manage a plurality of charging points.

According to an optional embodiment of the present application, the charging point management system is a charging point aggregation platform.

According to an optional embodiment of the present application, the plurality of charging points comprises at least two different charging points.

According to a fourth aspect of the present application, there is provided a charging point system comprising the aforementioned charging point management system and a plurality of charging points managed by the charging point management system.

According to an optional embodiment of the present application, the charging point system comprises the charging points, an operator system of a charging point operator responsible for the charging points, and a charging point aggregation platform, wherein the charging point aggregation platform is capable of acquiring information of the charging points via the operator system of the charging point operator responsible for the charging points.

According to a fifth aspect of the present application, there is provided a charging point configured to perform the aforementioned method for screening for an abnormal charging point.

The principles, features and advantages of the present application can be better understood from the following further detailed description of the present application provided with reference to the accompanying drawings.

### BRIEF DESCRIPTION OF THE DRAWINGS

FIG. 1 shows an example of a charging point system of the present application; and

FIG. 2 schematically shows an example of a method for screening for an abnormal charging point according to the present application in the form of a flow chart.

### DETAILED DESCRIPTION OF THE DRAWINGS

In order to make the technical problems to be solved by the present application, the technical solutions, and the beneficial technical effects clearer, the present application will be described below in further detail with reference to the accompanying drawings and a plurality of exemplary embodiments. It should be understood that the specific embodiments described herein are merely used to explain the present application, but are not used to limit the scope of protection of the present application.

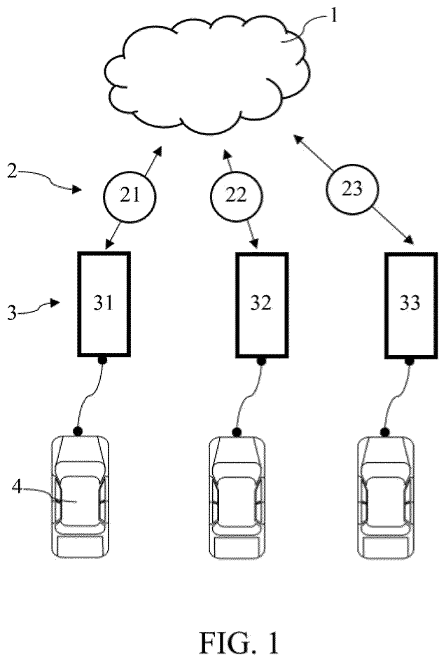

FIG. 1 shows an example of a charging point system of the present application. The charging point system includes a charging point management system and a plurality of charging points 3 managed by the charging point management system. Each charging point 3 is used to charge a vehicle 4.

In FIG. 1, the charging point management system is exemplarily a charging point aggregation platform 1. The charging points 3 managed by the charging point aggregation platform 1 may be charging points 3 from different charging point operators 2. Three different charging points 3 (i.e., a first charging point 31, a second charging point 32, and a third charging point 33) from three charging point operators 2 (i.e., a first charging point operator 21, a second charging point operator 22, and a third charging point operator 23) are exemplarily shown in FIG. 1. An operator system of each charging point operator 2 communicates with the charging point 3 owned thereby via a network, especially a wireless network, to monitor the charging point 3. The charging point aggregation platform 1 generally communicates only with the operator systems of the charging point operators 2 and acquires the information of the charging points 3 only from the operator systems of the charging point operators 2. Communication protocols and software designs of different charging point operators 2 are generally different from each other, so the charging point aggregation platform 1 generally does not directly manage the charging points 2, but the respective charging points are generally managed by the charging point operators 2 themselves. However, this is obviously inconvenient for the charging point aggregation platform 1.

For this reason, the present application proposes a method for screening for an abnormal charging point. In particular, it can help the charging point aggregation platform 1 to conveniently monitor the charging points 3 at the platform level on the basis of the charging point information obtained from the charging point operators 2 without additional modification to screen for an abnormal charging point.

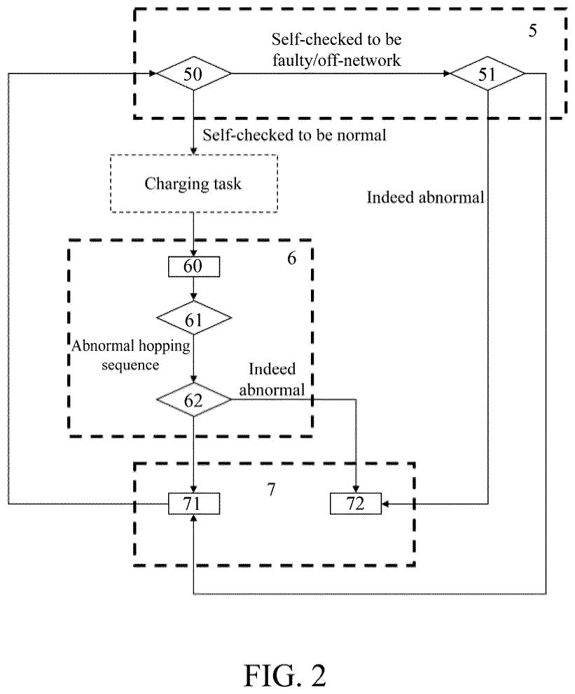

FIG. 2 schematically shows an example of a method for screening for an abnormal charging point according to the present application in the form of a flow chart.

As shown in FIG. 2, the method includes a screening process 6, and the screening process 6 includes the following steps:
an acquisition step 60, in which information of a charging interface state of a charging point 3 during at least one charging task of the charging point 3 is acquired; and
a screening step 61, in which for the at least one charging task, screening is performed to determine whether a hopping sequence of the charging interface state of the charging point 3 meets a specific hopping sequence, and if so, the charging point 3 is identified to be normal, or if not, the charging point 3 is identified as an abnormal charging point.

On the basis of the above-described method, it is possible to screen for an abnormal charging point in a very simple manner.

A charging task refers in particular to at least a duration starting from when a charging gun is pulled out of the charging point 3 until the moment in which the charging gun is inserted back into the charging point 3 again after charging has been completed. A charging task may in particular also be understood as a charging order, i.e., at least a duration starting from when a charging request is issued until charging is completed and an electric vehicle is disconnected from the charging point 3.

According to an exemplary embodiment, the charging interface state includes at least three states, namely A, B, and C, wherein A represents that a charging interface of the charging point 3 is idle, B represents that the charging interface of the charging point 3 is occupied but charging is not performed, and C represents that the charging interface of the charging point 3 is occupied and charging is performed. It is also conceivable that the charging interface state includes only two states, namely, A and C, or more states.

According to an exemplary embodiment, there are four specific hopping sequences:
A-B-C-B-A;
A-B-C-A;
A-C-B-A; and
A-C-A.

In the screening step 61, if the hopping sequence of the charging interface state of the charging point 3 does not meet any one of the four specific hopping sequences, then the charging point 3 is identified as an abnormal charging point.

The following situations are additionally taken into account here: after the charging gun is inserted into the vehicle, the user may not directly start charging because he/she wants to smoke or make a phone call, but start charging after doing these miscellaneous things, and in this case, the hopping sequence of the charging interface state is A-B-C-A or A-B-C-B-A; or, similarly, after the charging is completed, it is possible that the user will not directly end the charging, but will end the charging with a slight delay, and in this case, the hopping sequence of the charging interface state is A-C-B-A or A-B-C-B-A.

According to an exemplary embodiment, referring to FIGS. 1 and 2, in the acquisition step 60, the charging point aggregation platform 1 acquires the information of each charging point 3 via the operator system of the charging point operator 2 responsible for the charging point 3. In the screening step 61, the charging point aggregation platform 1 performs screening with respect to the hopping sequence of the charging interface state of the charging point 3. In the above manner, the charging point aggregation platform 1 can simply and reliably screen for abnormal charging points uniformly at a platform level on the basis of information obtained from charging point operators 2.

According to an exemplary embodiment, in the screening step 61, screening is performed to determine whether the duration for which the charging interface state is C exceeds a charging duration threshold and/or screening is performed to determine whether the duration taken to complete each charging task exceeds a task duration threshold. The charging duration threshold or the task duration threshold may be set to 12 hours, for example. If the charging duration threshold and/or the task duration threshold is exceeded in a charging task, then the charging point 3 may be identified as an abnormal charging point. It is also conceivable that an abnormal charging point is identified to indeed be abnormal if the charging duration threshold and/or the task duration threshold is exceeded three or more times a week.

According to an exemplary embodiment, as shown in FIG. 2, the screening process 6 includes an anomaly count monitoring step 62, in which if a charging point 3 is identified as an abnormal charging point twice in succession in two screening processes 6 performed for a current charging task and a previous charging task and/or if the number of times the charging point 3 is identified as an abnormal charging point in a plurality of screening processes 6 performed for a plurality of charging tasks up to the current charging task exceeds a predetermined count, then the charging point 3 is identified to indeed be abnormal. By performing deep screening in at least two charging tasks, maintenance costs can be appropriately reduced while ensuring screening accuracy. In the case of a plurality of charging tasks, it is exemplarily conceivable that, in five consecutive charging tasks, if a charging point 3 is identified as an abnormal charging point in the first, third, and fifth charging tasks by means of the screening process 6, the charging point 3 may also be identified to indeed be abnormal accordingly. Obviously, other appropriate setting schemes for anomaly count monitoring in terms of the count may also be conceivable.

According to an exemplary embodiment, as shown in FIG. 2, the method includes a handling process 7 that is performed for an abnormal charging point.

According to an exemplary embodiment, as shown in FIG. 2, the handling process 7 includes a restart step 71 in which the charging point 3 is restarted. The fact that a charging point 3 has an anomaly in a charging task does not absolutely mean that the charging point 3 is indeed abnormal. Recovery from an anomaly caused by, for example, software, can be made by restarting the abnormal charging point. It is further conceivable that, as shown in FIG. 2, the restart step 71 is performed for a charging point 3 that is not identified to indeed be abnormal in the anomaly count monitoring step 62.

According to an exemplary embodiment, as shown in FIG. 2, the handling process 7 includes a handling step 72 in which a signal indicating that the charging point 3 is abnormal is outputted and/or the charging point 3 is shut down and/or the charging point 3 is made non-selectable by a user on an application program.

Outputting the signal indicating that the charging point 3 is abnormal may include outputting to a user by means of the charging point 3, outputting to a platform manager by means of a charging point management system, and outputting to the user by means of an associated mobile device, such as a mobile phone. Obviously, the output is mainly a visual output, but alternatively or additionally, an audible output and/or a tactile output is conceivable.

At present, charging requests and payments are increasingly made by means of apps on mobile phones, and by making an abnormal charging point non-selectable by a user in an application program, it is possible to conveniently prevent the user from using the abnormal charging point.

It is conceivable that the handling step 72 is performed directly for a charging point 3 identified as an abnormal charging point, or, as shown in FIG. 2, the handling step 72 is performed only after the charging point 3 is identified to indeed be abnormal. It is exemplarily conceivable that abnormal charging points are classified for handling according to the frequencies at which the charging points 3 are used. For example, for a charging point 3 that is used at a high frequency, the charging point 3 that is identified as an abnormal charging point may be directly shut down to prevent a plurality of subsequent users from using the charging point 3, and the charging point management system may be notified as soon as possible for inspection and repair, whereas for a charging point 3 that is used at a low frequency, the charging point 3 may be shut down only after it is identified to indeed be abnormal.

According to an exemplary embodiment, as shown in FIG. 2, the method includes a self-checking monitoring process 5, in which self-checking conditions of the charging point 3 are monitored at least before the charging task. Thus, charging points that cannot even enter the charging task are excluded in advance.

According to an exemplary embodiment, as shown in FIG. 2, the self-checking monitoring process 5 includes a self-checking monitoring step 50, in which whether the charging point 3 is self-checked to be in a fault state and/or off-network state is monitored, and if so, the charging point 3 is identified as an abnormal charging point. For an abnormal charging point, the restart step 71 or the handling step 72 may be performed. It is also conceivable that in the self-checking monitoring step 50, the duration of the fault state and/or off-network state is additionally taken into account when the charging point is identified to be abnormal. If the charging point 3 recovers again after the self-checking briefly determines that it is in the fault state or off-network state, the charging point 3 is still regarded as normal.

According to an exemplary embodiment, as shown in FIG. 2, the self-checking monitoring process 5 includes a restart count monitoring step 51. If the result of the self-checking monitoring step 50 is positive, then the restart count monitoring step 51 is performed. In the restart count monitoring step 51, if it is detected that the number of times the charging point 3 is restarted exceeds a preset count, then the charging point 3 is identified to indeed be abnormal. It is conceivable that, as shown in FIG. 2, the handling step 72 is performed for the charging point 3 that is identified to indeed be abnormal by means of the restart count monitoring step 51, and the restart step 71 is performed for the charging point 3 that is not identified to indeed be abnormal in the restart count monitoring step 51.

In the above description, the method of the present application has mainly been described with respect to the charging point aggregation platform. Alternatively, however, it is also conceivable that: the method of the present application is implemented directly by the charging point or by the charging point management system of the charging point operator itself. For example, during each charging task, the acquisition step and the screening step are both performed at the charging point, and the charging point feeds back the screening result to the charging point management system of the charging point operator after completing the screening. Alternatively, the charging point transmits the charging interface state to the charging point management system of the charging point operator via a network, and the charging point management system of the charging point operator performs the screening step after acquiring the information of the charging interface state of the charging point.

Some beneficial effects have been described in the specification. It needs to be pointed out that these beneficial effects should not be construed as mandatory requirements, but may only be achieved in certain application scenarios.

Although particular embodiments of the present application have been described in detail herein, the particular embodiments are given merely for the purpose of explanation, and should not be considered to limit the scope of the present application. Various substitutions, alterations, and modifications may be conceived of without departing from the spirit and scope of the present application.

1-14. (canceled)

15. A method for screening for an abnormal charging point, comprising:
a screening process (6), wherein the screening process (6) comprises:
an acquisition step (60), in which information of a charging interface state of a charging point (3) during at least one charging task of the charging point (3) is acquired; and
a screening step (61), in which for each charging task, screening is performed to determine whether a hopping sequence of the charging interface state of the charging point (3) meets a specific hopping sequence, and when so, the charging point (3) is identified to be normal, or when not, the charging point (3) is identified as an abnormal charging point.

16. The method according to claim 15:
wherein the charging interface state comprises at least three states including A, B, and C and wherein A represents that a charging interface of the charging point (3) is idle, B represents that the charging interface of the charging point (3) is occupied but charging is not performed, and C represents that the charging interface of the charging point (3) is occupied and charging is performed;
wherein there are four specific hopping sequences:
A-B-C-B-A;
A-B-C-A;
A-C-B-A; and
A-C-A;
wherein in the screening step (61), when the hopping sequence of the charging interface state of the charging point (3) does not meet any one of the four specific hopping sequences, then the charging point (3) is identified as an abnormal charging point.

17. The method according to claim 15, wherein:
in the acquisition step (60), a charging point aggregation platform (1) acquires the information of the charging point (3) via an operator system of a charging point operator (2) responsible for the charging point (3); and
in the screening step (61), the charging point aggregation platform (1) performs screening with respect to the hopping sequence of the charging interface state of the charging point (3).

18. The method according to claim 15, further comprising at least one of:
the screening process (6) comprises an anomaly count monitoring step (62), in which when the charging point (3) is identified as an abnormal charging point twice in succession in two screening processes (6) performed for a current charging task and a previous charging task and/or when a number of times the charging point (3) is identified as an abnormal charging point in a plurality of screening processes (6) performed for a plurality of charging tasks up to the current charging task exceeds a predetermined count, then the charging point (3) is identified to be abnormal;
a handling process (7) that is performed for an abnormal charging point; and
a self-checking monitoring process (5), in which self-checking conditions of the charging point (3) are monitored at least before the charging task.

19. The method according to claim 18, further comprising at least one of:
the handling process (7) comprises a restart step (71) in which the charging point (3) is restarted;
the handling process (7) comprises a handling step (72) in which a signal indicating that the charging point (3) is abnormal is outputted and/or the charging point (3) is shut down and/or the charging point (3) is made non-selectable by a user on an application program; and
the self-checking monitoring process (5) comprises a self-checking monitoring step (50), in which whether the charging point (3) is self-checked to be in a fault state and/or off-network state is monitored, and when a result of the self-checking monitoring step (50) is positive, the charging point (3) is identified as an abnormal charging point.

20. The method according to claim 19, further comprising at least one of:
the handling step (72) is performed for the charging point (3) identified to be abnormal by the anomaly count monitoring step (62);
the restart step (71) is performed for the charging point (3) not identified to be abnormal in the anomaly count monitoring step (62); and
in the self-checking monitoring step (50), a duration of the fault state and/or off-network state is additionally taken into account when the charging point is identified to be abnormal.

21. The method according to claim 19, wherein:
the self-checking monitoring process (5) comprises a restart count monitoring step (51), when the result of the self-checking monitoring step (50) is positive, then the restart count monitoring step (51) is performed, and in the restart count monitoring step (51), when it is detected that a number of times the charging point (3) is restarted exceeds a preset count, then the charging point (3) is identified to be abnormal;
the handling step (72) is performed for the charging point (3) identified to be abnormal by the restart count monitoring step (51); and
the restart step (71) is performed for the charging point (3) not identified to be abnormal in the restart count monitoring step (51).

22. The method according to claim 16, wherein in the screening step (61), screening is performed to determine whether a duration for which the charging interface state is C exceeds a charging duration threshold and/or screening is performed to determine whether a duration taken to complete each charging task exceeds a task duration threshold.

23. A computer program product, comprising computer program instructions, wherein, when the computer program instructions are executed by one or more processors, the one or more processors are capable of performing the method for screening for an abnormal charging point according to claim 15.

24. A charging point management system configured to perform the method for screening for an abnormal charging point according to claim 15 to manage a plurality of charging points (3).

25. The charging point management system according to claim 24, comprising at least one of:
the charging point management system is a charging point aggregation platform (1); and
the plurality of charging points (3) comprises at least two different charging points (3).

26. A charging point system, comprising:
the charging point management system according to claim 24; and
a plurality of charging points (3) managed by the charging point management system.

27. The charging point system according to claim 26, further comprising:
an operator system of a charging point operator (2) responsible for the plurality of charging points (3); and
a charging point aggregation platform (1), wherein the charging point aggregation platform (1) is capable of acquiring information of the plurality of charging points (3) via the operator system.

28. A charging point (3) configured to perform the method for screening for an abnormal charging point according to claim 15.
